(19) United States
(12) Patent Application Publication
(10) Pub. No.: US 2023/0347419 A1
(43) Pub. Date: Nov. 2, 2023

(54) METHOD OF USING A DRILL BIT AND METHOD OF PREPARING A DRILL BIT

(71) Applicant: GUANGDONG DTECH TECHNOLOGY CO., LTD., Dongguan (CN)

(72) Inventors: Xin ZHENG, Dongguan (CN); Hanquan CHEN, Dongguan (CN)

(21) Appl. No.: 18/031,338

(22) PCT Filed: Nov. 11, 2020
(86) PCT No.: PCT/CN2020/128174

§ 371 Date: Apr. 11, 2023

(30) Foreign Application Priority Data
Oct. 22, 2020 (CN) 202011140390.4

(51) Int. Cl. B23B 51/02; B23B 35/00

(52) U.S. Cl. CPC B23B 35/00; B23B 51/02

(57) ABSTRACT

A method of using a drill bit includes: S11, drilling, by a drill bit, a through hole in a board to be processed, and collecting a feedback time T of each conducting layer of the board by a drill tip; S12, determining a target layer and a reference layer of the board, and calculating a time difference t between the target layer and the reference layer; S13, determining a distance H between the target layer and the reference layer according to the time difference t and a drilling speed v of the drill bit; and S14, performing a controlled depth drilling by starting from the reference layer on the basis of the through hole and taking the distance H as a drilling depth.

### CROSS-REFERENCE TO RELATED APPLICATION(S)

This is a national stage application filed under 37 U.S.C. 371 based on International Patent Application No. PCT/CN2020/128174, filed on 11 Nov. 2020, which claims priority to Chinese Patent Application No. 202011140390.4, filed with the China National Intellectual Property Administration (CNIPA) on 22 October, 2020, the disclosure of which is incorporated herein by reference in its entirety.

### TECHNICAL FIELD

The present application relates to the technical field of machining tools, for example, to method of using a drill bit and a method of preparing a drill bit.

### BACKGROUND

Plated through holes (PTH) in the multilayer printed circuit board (PCB) have the function that via the PTHs, the inner power layer and the ground layer are in communication. When the system enters high-speed signal transmission, the PTHs will become bottlenecks and obstacles of signal integrity. The PTHs are like extra “stubs” in the transmission line, and act as notch filters. In a signal transmission line, when such stubs appear at two places, an oscillation section will be formed, and whether it is filtering or oscillation, it will cause damage to high-speed signal transmission and distort the signal. At present, the widely used method is the back drilling method. However, in one aspect, the back drilling method is heavily dependent on the process, and in another aspect, the depth of the back drilling is not easy to control.

### SUMMARY

A method of using a drill bit and a method of preparing a drill bit are provided according to the present application, so that when a controlled depth drilling is performed with a drill bit, the drilling depth can be accurately controlled, without depending on the process flow, and the machining efficiency and machining accuracy can be improved.

A method of using a drill bit is provided according to an embodiment. The drill bit includes a drill shank, a drill edge and a drill tip which are connected in sequence, the drill tip is capable of conducting electricity and the drill edge is covered with a non-conductive film layer, the method of using a drill bit includes the following steps: S11, S12, S13 and S14.

In the step S11, a through hole is drilled by the drill bit in a board to be processed, and a feedback time T of each conductive layer of the board to be processed is collected by the drill tip.

In the step S12, a target layer and a reference layer of the board to be processed are determined, and a time difference t between the target layer and the reference layer is calculated.

In the step S13, a distance H between the target layer and the reference layer is determined according to the time difference t and a drilling speed v of the drill bit.

In the step S14, a controlled depth drilling is performed by starting from the reference layer on the basis of the through hole and taking the distance H as a drilling depth.

Optionally, in the step S13, the distance H = the time difference t × the drilling speed v.

Optionally, the diameter of a drilled hole of the controlled depth drilling is larger than the diameter of the through hole.

Optionally, the drill bit further includes a transition part, and one end of the transition part is connected to the drill shank and another end of the transition part is connected to the drill edge.

Optionally, the transition part is in a truncated cone shape.

A method of preparing a drill bit, which is used for preparing the above-described drill bit, is provided according to an embodiment of the present application, and the method of preparing the drill bit includes: steps S21, S22, S23, S24 and S25.

In step S21, a raw material bar is machined into a semi-finished product with a contour of the drill edge.

In step S22, a spiral groove is formed in the contour of the drill edge of the semi-finished product.

In step S23, a free end of the spiral groove is sharpened to form the drill tip.

In step S24, the non-conductive film layer is coated on the contour part of the drill edge.

In step S25, the non-conductive film layer on the drill tip part is ground off.

Optionally, the drill bit further includes a transition part, and one end of the transition part is connected to the drill shank and another end of the transition part is connected to the drill edge; and the step S21 includes: machining the raw material bar into a semi-finished product having the drill shank, the transition part and the contour of the drill edge.

Optionally, in the step S21, the raw material bar is machined into the semi-finished product having the drill shank, the transition part and the contour of the drill edge by using a rough and fine grinding apparatus to perform cylindrical grinding and mismatch discrepancy machining.

Optionally, in the step S24, the contour part of the drill edge is coated with the non-conductive film layer by a method of PVD or a method of CVD.

The drill bit according to the present application includes the drill shank, the drill edge and the drill tip which are connected in sequence, the drill tip is capable of conducting electricity, and the drill edge is covered with a non-conductive film layer. When a through hole is drilled in a board to be processed by the drill bit, since the drill bit can conduct electricity, first, a feedback time T of each conductive layer of the board to be processed is collected by the drill tip, and then a target layer and a reference layer of the board to be processed are determined, and a time difference t between the target layer and the reference layer is calculated; a distance H between the target layer and the reference layer is determined according to the time difference t and a drilling speed v of the drill bit; and a controlled depth drilling is performed by starting from the reference layer on the basis of the through hole and taking the distance H as a drilling depth. Performing the controlled depth drilling by the above method can accurately control the drilling depth, thereby getting rid of the dependence on the board thickness and the process flow control, and improving the machining efficiency and machining accuracy.

### BRIEF DESCRIPTION OF DRAWINGS

FIG. 1 is a flow chart of main steps of a method of using a drill bit according to an embodiment of the present application;

FIG. 2 is a schematic structural diagram of a drill bit according to an embodiment of the present application;

FIG. 3 is a schematic structural diagram of a board to be processed with a through hole drilled therein according to an embodiment of the present application;

FIG. 4 is a schematic structural diagram of a board to be processed with a controlled depth drilling performed therein according to an embodiment of the present application;

FIG. 5 is a flow chart of main steps of a method of preparing a drill bit according to an embodiment of the present application; and

FIG. 6 is a flow chart of detailed steps of a method of preparing a drill bit according to an embodiment of the present application

Reference numerals in the drawings

| | |
|---|---|
| 1 | drill bit |
| 11 | drill shank |
| 12 | drill edge |
| 13 | drill tip |
| 14 | transition part |
| 15 | non-conductive film layer |
| 2 | board to be processed |
| 21 | through hole |
| 22 | drilled hole |

### DETAILED DESCRIPTION

In the description of this application, unless otherwise clearly specified and limited, the terms “jointed”, “connected” and “fixed” should be understood in a broad sense, for example, it can be a fixed connection, a detachable connection, or integrally formed; it can be a mechanical connection or an electrical connection; it can be a direct connection or an indirect connection through an intermediary, and it can be the internal communication of two components or the interaction relationship between two components. Those of ordinary skill in the art can understand the specific meanings of the above terms in this application according to specific situations.

In this application, unless otherwise expressly specified and limited, a first feature being “on” or “under” a second feature may include direct contact between the first and second features, and may also include the first and second features not in direct contact but in contact through another feature between them. Moreover, the first feature is “over”, “above” and “on” the second feature include that the first feature is directly above and obliquely above the second feature, or simply means that the first feature is horizontally higher than the second feature. The first feature is “beneath”, “below” and “under” the second feature include that the first feature is directly below and obliquely below the second feature, or simply means that the first feature has a lower level than the second feature.

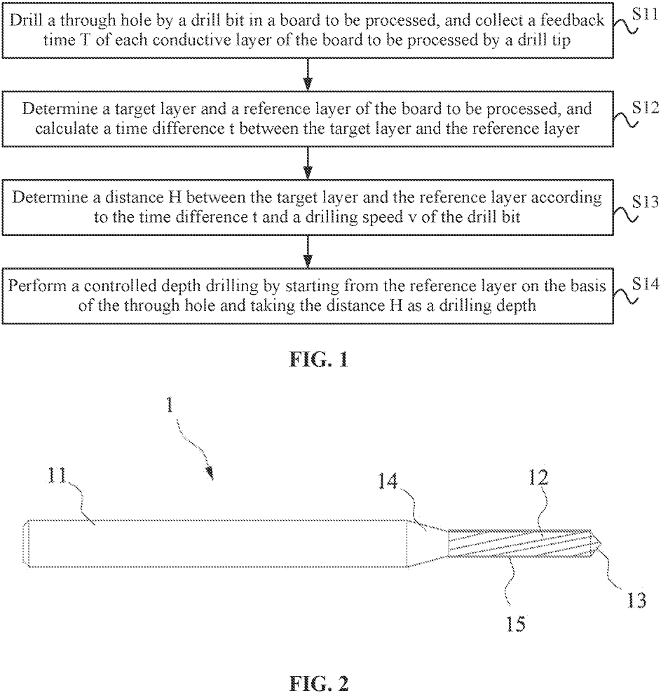

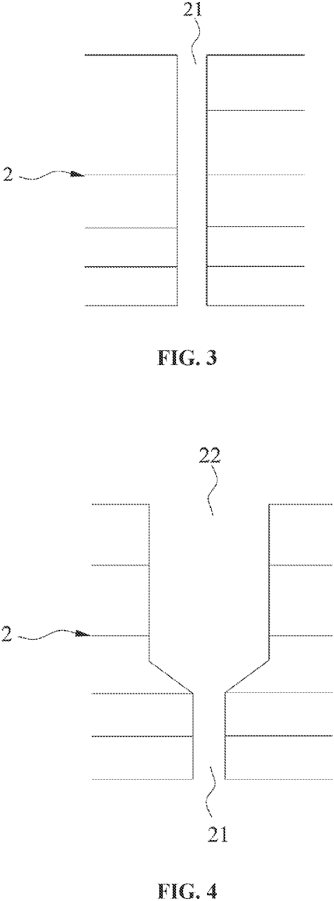

As shown in FIG. 1 to FIG. 4, the drill bit 1 includes a drill shank 11, a drill edge 12 and a drill tip 13 which are connected in sequence, the drill tip 13 is conductive and the drill edge 12 is covered with a non-conductive film layer 15, and the using method of using the drill bit includes the following steps S11, S12, S13, S14.

In the step S11, a through hole 21 is drilled in a board 2 to be processed by a drill bit 1, and a feedback time T of each conductive layer of the board 2 to be processed is collected by the drill tip 13.

The board 2 to be processed includes multiple conductive layers arranged at intervals. When the drill bit 1 is used to drill the through hole 21 in the board 2 to be processed, since the drill tip 13 is conductive and the drill edge 12 is covered with the non-conductive film layer 15, the drill edge 12 cannot conduct electricity, so when the drill tip 13 touches the conductive layers of the board 2 to be processed, the feedback time T of each the conductive layer can be collected. The specific working principle of the drill tip 13 collecting the feedback times of the conductive layers is a related technology, and will not be repeated here. In this embodiment, the board 2 to be processed is a PCB board, and in other embodiments, the board 2 to be processed can also be of other structures.

In the step S12, a target layer and a reference layer of the board 2 to be processed are determined, and a time difference t between the target layer and the reference layer is calculated.

In this embodiment, the reference layer can be a surface layer or an inner layer, which can be selected according to machining conditions. After the reference layer and the target layer are selected, the time difference t between the target layer and the reference layer is calculated according to the feedback time T collected by the drill tip 13 in the step S11.

In the step S13, a distance H between the target layer and the reference layer is determined according to the time difference t and a drilling speed v.

Optionally, in the step S13, the distance H = the time difference t × the drilling speed v. The distance between the target layer and the reference layer can be determined by the time difference t between the target layer and the reference layer and the drilling speed v of the drill bit 1. Since the drilling speed v of the drill bit 1 can be precisely controlled by a machine, it can be guaranteed that the numerical value of the distance H obtained by the above method is more precise.

In the step S14, a controlled depth drilling is performed by starting from the reference layer on the basis of the through hole 21 and taking the distance H as a drilling depth.

Optionally, the diameter of the drilled hole 22 of the controlled depth drilling is larger than the diameter of the through hole 21. In order to ensure that the diameter of the drilled hole 22 of the controlled depth drilling is greater than the diameter of the through hole 21, an outer diameter of the drill edge 12 of the drill bit 1 used in the above step S14 should be greater than an outer diameter of the drill edge 12 of the drill bit 1 used in drilling the through hole 21 by 2 mm to 3 mm. The controlled depth drilling is performed on the basis of the through hole 21 by the above method, the drilling depth can be precisely controlled, so as to get rid of the dependence on the board thickness and process flow control, and improve the machining efficiency and machining accuracy.

Optionally, as shown in FIG. 2, the drill bit 1 further includes a transition part 14, one end of the transition part 14 is connected to the drill shank 11 and another end of the transition part 14 is connected to the drill edge 12. Optionally, the transition part 14 is in a truncated cone shape. In this embodiment, an end with a large outer diameter of the transition part 14 is connected to the drill shank 11, and an end with a small outer diameter of the transition part 14 is connected to the drill edge 12. In other embodiments, the transition part 14 may also have other shapes, or the transition part 14 may not be provided.

In this embodiment, the non-conductive film layer 15 is a DLC coating. The DLC coating has advantages of high hardness, low friction coefficient, good film compactness and chemical stability, etc., and can prolong the service life of the drill edge 12. As for whether the non-conductive film layer 15 is coated on the positions of the drill shank 11 and the transition part 14, there is no limitation here, and it can be adaptively selected according to practical use requirements. In other embodiments, the non-conductive film layer 15 may also be other coatings.

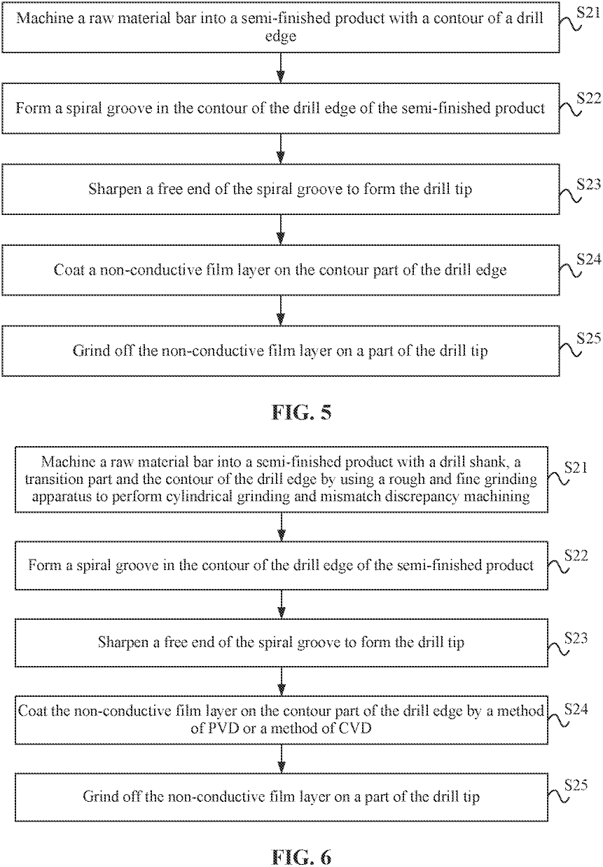

A method of preparing a drill bit, which is used for preparing the above-described drill bit 1, is further provided according to the present application. As shown in FIG. 5 and FIG. 6, the method of preparing a drill bit includes the following steps: S21, S22, S23, S24 and S25.

In step S21, a raw material bar is machined into a semi-finished product having a contour of the drill edge 12.

Optionally, a raw material bar is machined into a semi-finished product having the drill shank 11, the transition part 14 and a contour of the drill edge 12. That is, the raw material bar is machined to have structures of the drill shank 11 and the transition part 14 of the drill bit 1 and the contour of the drill edge 12 to form a semi-finished product. In this embodiment, a rough and fine grinding apparatus is used to perform a cylindrical grinding and mismatch discrepancy machining to machine the raw material bar into a semi-finished product. In other embodiments, other apparatuses or other machining techniques can also be used, but the technical requirements of the semi-finished product should be guaranteed.

In step S22, a spiral groove is formed in the contour of the drill edge 12 of the semi-finished product.

After the spiral groove is provided in the outer contour of the drill edge 12, the drill edge 12 is partially machined, and the waste material in the process of drilling can be discharged through the spiral groove. The specific shape, size and quantity of the spiral grooves are not limited here, and can be adaptively selected according to practical use requirements.

In step S23, a free end of the spiral groove is sharpened to form a drill tip 13.

Next, an end of the spiral groove away from the transition table 14 is ground to form the drill tip 13. As for the length of the drill tip 13, it is not limited here, and it can be adaptively set according to practical use requirements.

In step S24, the non-conductive film layer 15 is coated on the contour part of the drill edge 12.

In this embodiment, the non-conductive film layer 15 is coated by a method of PVD or a method of CVD. The method of PVD or the method of CVD has a good coating effect and can ensure the performance of use of the non-conductive film layer 15. In other embodiments, other methods may also be used to coat the non-conductive film layer 15.

In step S25, the non-conductive film layer 15 on the drill tip 13 part is ground off.

Since the feedback signal needs to be collected through the drill tip 13, it is necessary to ensure that a part of the drill tip 13 can conduct electricity, so the non-conductive film layer 15 of a part of the drill tip 13 should be ground off at last to ensure the conductive effect. In other embodiments, the non-conductive film layer 15 may be coated on only the outside of the drill edge 12 in the step S24.

In this embodiment, the drill bit 1 is prepared by the above-described method of preparing the drill bit, and the above-described method of using the drill bit is used to drill a hole in the board 2 to be processed, which can precisely control the depth of drilling when the controlled depth drilling is performed, thereby getting rid of the dependent on the thickness of the board and the process flow control and improving machining efficiency and machining accuracy.

What is claimed is:

1. A method of using a drill bit, wherein the drill bit comprises a drill shank, a drill edge and a drill tip which are connected in sequence, the drill tip is capable of conducting electricity, and the drill edge is covered with a non-conductive film layer, the method of using the drill bit comprises following steps:
drilling a through hole by the drill bit in a board to be processed, and collecting a feedback time T of each conductive layer of the board to be processed by the drill tip;
determining a target layer and a reference layer of the board to be processed, and calculating a time difference t between the target layer and the reference layer;
determining a distance H between the target layer and the reference layer according to the time difference t and a drilling speed v of the drill bit; and
performing a controlled depth drilling by starting from the reference layer on a basis of the through hole and taking the distance H as a drilling depth.

2. The method of using the drill bit according to claim 1, wherein in determining the distance H between the target layer and the reference layer according to the time difference t and the drilling speed v of the drill bit, the distance H = the time difference t × the drilling speed v.

3. The method of using the drill bit according to claim 1, wherein a diameter of a drilled hole of the controlled depth drilling is larger than a diameter of the through hole.

4. The method of using the drill bit according to claim 1, wherein the drill bit further comprises a transition part, one end of the transition part is connected to the drill shank, and another end of the transition part is connected to the drill edge.

5. The method of using the drill bit according to claim 4, wherein the transition part is in a truncated cone shape.

6. A method of preparing a drill bit, used for preparing a drill bit, wherein the drill bit comprises a drill shank, a drill edge and a drill tip which are connected in sequence, the drill tip is capable of conducting electricity, and the drill edge is covered with a non-conductive film layer; the method of preparing the drill bit comprising:
machining a raw material bar into a semi-finished product with a contour of the drill edge;
forming a spiral groove in the contour of the drill edge of the semi-finished product;
sharpening a free end of the spiral groove to form the drill tip;
coating the non-conductive film layer on a contour part of the drill edge; and
grinding off a part of the non-conductive film layer on the drill tip.

7. The method of preparing the drill bit according to claim 6, wherein the drill bit further comprises a transition part, one end of the transition part is connected to the drill shank,
and another end of the transition part is connected to the drill edge; and
machining the raw material bar into the semi-finished product with the contour of the drill edge comprises: machining the raw material bar into a semi-finished product having the drill shank, the transition part and the contour of the drill edge.

8. The method of preparing the drill bit according to claim 7, wherein, in machining the raw material bar into the semi-finished product with the contour of the drill edge, the raw material bar is machined into the semi-finished product having the drill shank, the transition part and the contour of the drill edge by using a rough and fine grinding apparatus to perform cylindrical grinding and mismatch discrepancy machining.

9. The method of preparing the drill bit according to claim 6, wherein, in coating the non-conductive film layer on the contour part of the drill edge, the contour part of the drill edge is coated with the non-conductive film layer by a method of PVD or a method of CVD.
